(19) United States
(12) Patent Application Publication
(10) Pub. No.: US 2026/0190741 A1
(43) Pub. Date: Jul. 2, 2026

(54) LIGHT EMITTING DISPLAY APPARATUS

(71) Applicant: LG Display Co., Ltd., Seoul (KR)

(72) Inventors: Miso Kim, Paju-si (KR); Byungjin Kim, Paju-si (KR); Hanseok Lee, Paju-si (KR); Donggu Kim, Paju-si (KR)

(73) Assignee: LG Display Co., Ltd., Seoul (KR)

(21) Appl. No.: 19/436,123

(22) Filed: Dec. 30, 2025

(30) Foreign Application Priority Data
Dec. 30, 2024 (KR) 10-2024-0201446

(51) Int. Cl. H10K 59/38; H10K 59/122; H10K 59/131

(52) U.S. Cl. CPC H10K 59/38; H10K 59/122; H10K 59/131

(57) ABSTRACT

A light emitting display apparatus according to one or more embodiments of the present disclosure may include a substrate including a plurality of subpixels having an emission area and a non-emission area, a pixel circuit disposed in the non-emission area on the substrate, at least one insulating layer disposed on the pixel circuit, a color filter disposed on the at least one insulating layer and corresponding to at least some of the plurality of subpixels, a first overcoat layer disposed on the color filter, a second overcoat layer disposed on the at least one insulating layer between color filters that are adjacent to each other, and a reflective electrode disposed on the first overcoat layer and the second overcoat layer.

### CROSS-REFERENCE TO RELATED APPLICATION

This application claims the benefit of and priority to Korean Patent Application No. 10-2024-0201446, filed in the Republic of Korea on Dec. 30, 2024, the entirety of which is incorporated herein by reference for all purposes.

### BACKGROUND

### Technical Field

The present disclosure relates to a light emitting display apparatus.

### Discussion of the Related Art

With the advancement of the information age, the demand for a display apparatus for displaying an image has increased in various forms. Therefore, various types of display apparatuses, such as a liquid crystal display (LCD) apparatus, an organic light emitting display (OLED) apparatus, a micro light emitting diode (LED) display apparatus, and a quantum dot display (QD) apparatus, have been recently used.

Among light emitting display apparatuses, an organic light emitting display apparatus is a self-luminance type that injects holes and electrons into an emission layer from an anode electrode for hole injection and a cathode electrode for electron injection, respectively, so that excitons formed by the recombination of the injected holes and electrons emit light as they fall from an excited state to a ground state, thereby displaying an image.

In such a light emitting display apparatus, a portion of light emitted from a light emitting device may fail to be emitted to the outside due to total reflection occurring at interfaces or between layers inside a display panel. This may cause a problem of reduced light extraction efficiency of the light emitting display apparatus.

### SUMMARY

Accordingly, embodiments of the present disclosure are directed to a light emitting display apparatus that substantially obviate one or more problems due to limitations and disadvantages of the related art.

One or more embodiments of the present disclosure may provide a light emitting display apparatus capable of improving light extraction efficiency of light emitted from a light emitting device.

One or more embodiments of the present disclosure may provide a light emitting display apparatus capable of expanding an emission area by implementing an auxiliary emission area between adjacent subpixels while preventing or suppressing light leakage.

One or more embodiments of the present disclosure may provide a light emitting display apparatus capable of improving light extraction efficiency, additionally securing an emission area, and reducing overall power consumption to enable low-power driving.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a light emitting display apparatus may comprise a substrate including a plurality of subpixels having an emission area and a non-emission area, a pixel circuit disposed in the non-emission area on the substrate, at least one insulating layer disposed on the pixel circuit, a color filter disposed on the at least one insulating layer and corresponding to at least some of the plurality of subpixels, a first overcoat layer disposed on the color filter, a second overcoat layer disposed on the at least one insulating layer between color filters that are adjacent to each other, and a reflective electrode disposed on the first overcoat layer and the second overcoat layer.

According to one or more embodiments of the present disclosure, a light emitting display apparatus capable of improving light extraction efficiency of light emitted from a light emitting device may be provided.

According to one or more embodiments of the present disclosure, a light emitting display apparatus capable of expanding an emission area by implementing an auxiliary emission area between adjacent subpixels while preventing or suppressing light leakage may be provided.

According to one or more embodiments of the present disclosure, a light emitting display apparatus capable of improving light extraction efficiency, additionally securing an emission area, and reducing overall power consumption to enable low-power driving may be provided.

The light emitting display apparatus according to one or more embodiments of the present disclosure may improve light extraction efficiency, additionally secure an emission area, and reduce overall power consumption to enable low-power driving, thereby realizing an ESG (Environmental, Social, and Governance) effect capable of reducing production energy.

The effects of the present disclosure are not limited to the aforesaid, but other effects not described herein can be clearly understood by those skilled in the art from the following descriptions.

It is to be understood that both the foregoing general description and the following detailed description are by way of example and explanatory and are intended to provide further explanation of the inventive concepts as claimed.

### BRIEF DESCRIPTION OF THE DRAWINGS

The accompanying drawings, which are included to provide a further understanding of the present disclosure, are incorporated in and constitute a part of this application, illustrate example embodiments of the present disclosure, and together with the description serve to explain various principles and examples of the present disclosure.

FIG. 1 illustrates a light emitting display apparatus according to an example embodiment of the present disclosure.

FIG. 2 illustrates a circuit diagram of a subpixel of a light emitting display apparatus according to an example embodiment of the present disclosure.

FIG. 3 illustrates a plurality of subpixels in a display panel according to an example embodiment of the present disclosure.

FIG. 4 is a cross-sectional view taken along line I-I′ in FIG. 3 according to an example embodiment of the present disclosure.

FIG. 5 illustrates an A region shown in FIG. 4 according to an example embodiment of the present disclosure.

FIG. 6 illustrates a B region shown in FIG. 4 according to an example embodiment of the present disclosure.

FIG. 7 illustrates a C region shown in FIG. 4 according to an example embodiment of the present disclosure.

FIG. 8 illustrates a D region shown in FIG. 4 according to an example embodiment of the present disclosure.

FIG. 9 illustrates adjacent subpixels according to another example embodiment of the present disclosure.

FIG. 10 illustrates adjacent subpixels according to another example embodiment of the present disclosure.

FIGS. 11 to 17 illustrate a method of manufacturing a display panel according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through various example embodiments described with reference to the accompanying drawings. The present disclosure may, however, be embodied in different forms and should not be construed as limited to the example embodiments set forth herein. Rather, these embodiments are examples and are provided so that this disclosure may be more thorough and complete, to assist those skilled in the art to understand the inventive concepts without limiting the protected scope of the present disclosure.

Shapes (e.g., dimensions, lengths, widths, heights, thicknesses, locations, radii, diameters, and areas), sizes, ratios, angles, numbers, and the like disclosed herein, including those illustrated in the drawings, are merely examples. Thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” or the like is used with respect to one or more elements, one or more other elements may be added unless a more limiting term, such as “only” or the like, is used. The terms used in the present disclosure are merely used to describe example embodiments and are not intended to limit the scope of the present disclosure. The terms of a singular form may include plural forms, and vice versa, unless the context clearly indicates otherwise.

In construing an element, the element is to be construed as including an error region although there is no explicit description thereof.

Where a positional relationship is described, for example, where the positional order is described as “on,” “above,” “below,” “beneath,” or “next,” the case of no contact therebetween may be included, unless a more limiting term like “just” or “direct” is used.

If a first element is described as positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

Where a temporal relationship is described, for example, where the temporal order is described as “after,” “subsequent,” “next,” or “before,” a case which is not continuous may be included, unless a more limiting term like “just” or “direct” is used.

It should be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) separately from the other element(s), and these are not used to define the essence, basis, order, or number of the elements.

For the expression that an element is “connected,” “coupled,” “attached,” or “adhered” to another element, or the like, the element may not only be directly connected, coupled, attached, or adhered to the other element, or the like, but also be indirectly connected, coupled, attached, or adhered to the other element, or the like, with one or more intervening elements disposed or interposed between the elements, unless otherwise specified.

For the expression that an element “overlaps” another element or the like, the element may not only directly contact or overlap with the other element, or the like, but also indirectly overlap the other element, or the like, with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each individual element of the first, second, and third elements.

Features of various embodiments of the present disclosure may be partially or entirely coupled to or combined with each other, may be technically associated with each other, and may be variously inter-operated, linked or driven together. The embodiments of the present disclosure may be implemented or carried out independently of each other, or may be implemented or carried out together in a co-dependent or associated relationship. In one or more aspects, the components of each apparatus according to various embodiments of the present disclosure may operatively be coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, and thickness illustrated in the drawings.

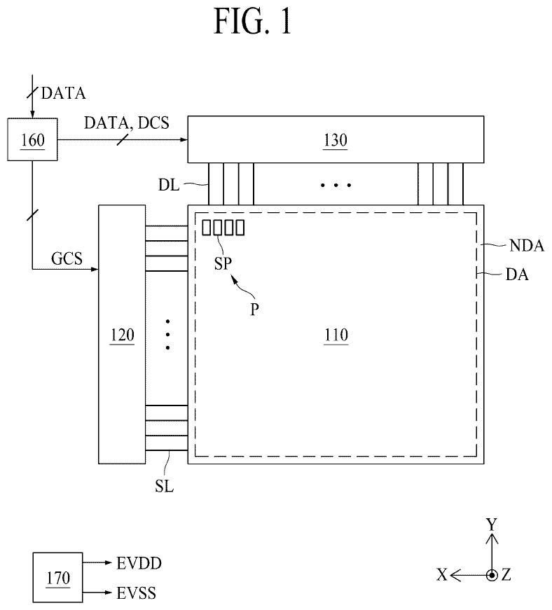

FIG. 1 illustrates a light emitting display apparatus according to an example embodiment of the present disclosure.

Hereinafter, an X-axis represents a direction parallel to a scan line (or a gate line), a Y-axis represents a direction parallel to a data line, and a Z-axis represents a height direction of the light emitting display apparatus.

A light emitting display apparatus according to an example embodiment of the present disclosure is implemented as an organic light emitting display apparatus, but may also be implemented as a liquid crystal display apparatus, a quantum dot lighting emitting diode display apparatus, or an electrophoretic display apparatus.

As shown in FIG. 1, the light emitting display apparatus according to an example embodiment of the present disclosure may include a display panel 110, a scan driver 120 (or a gate driver) embedded in the display panel 110, a data driver 130 connected to the display panel 110, a timing controller 160 configured to control the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of light of itself without forming a color filter. The subpixels SP may have one or more other light-emitting areas according to light-emitting characteristics. For example, the plurality of subpixels SP may be arranged in a stripe type or a quad type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate lines) connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages for an operation of all circuit configurations of the light emitting display apparatus by using an input voltage. The power circuit 170 may generate a first power source voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages for operations of the scan driver 120, the data driver 130, and the timing controller 160.

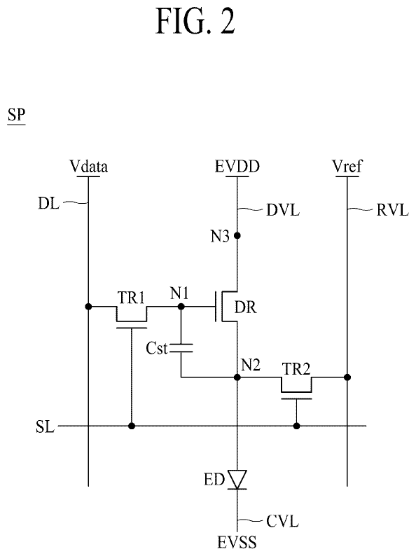

FIG. 2 illustrates a circuit diagram of a subpixel of a light emitting display apparatus according to an example embodiment of the present disclosure.

As shown in FIG. 2, each of pixels P includes the plurality of subpixels SP constituting a unit pixel. In each of the plurality of subpixels SP, there are a pixel circuit having 3T(Transistor)1C(Capacitor) including the driving transistor DR, the first switching transistor TR1, the second switching transistor TR2 and the storage capacitor Cst, and the light emitting device ED, but not limited thereto. Each subpixel SP may further include a compensation circuit. In this case, the subpixel SP may have various structures such as 3T2C, 4T1C, 4T2C, 5T1C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR may be a transistor for driving a light emitting device ED, and may include a first node N1 to which a data voltage Vdata is applied, a second node N2 connected to a pixel electrode (a first electrode or an anode electrode) of the light emitting device ED, and a third node N3 connected to a first power voltage line DVL (or a pixel power voltage line) to which a first power voltage EVDD (or a pixel power voltage) is applied. For example, the driving transistor DR may generate a data current from the first power voltage EVDD supplied through the first power voltage line DVL and supply the data current to the first electrode of the light emitting device ED.

The first switching transistor TR1 may serve to supply the data voltage Vdata supplied from the data line DL to the first node N1 of the driving transistor DR. The second switching transistor TR2 may serve to supply the reference voltage Vref supplied from the reference voltage line RVL to the second node N2 of the driving transistor DR or may output a voltage of the second node N2 of the driving transistor DR. The storage capacitor Cst may be connected between the first node N1 and the second node N2 of the driving transistor DR. The storage capacitor Cst may serve to maintain the data voltage Vdata supplied to the driving transistor DR for one frame, but embodiments of the present disclosure are not limited thereto.

The light emitting device ED may include the pixel electrode (first electrode or anode electrode) connected to the second node N2 of the driving transistor DR, and a reflective electrode (a second electrode or a cathode electrode) connected to a second power voltage line CVL. The light emitting device ED may emit light from an emission layer (or an organic emission layer) between the first electrode and the second electrode in response to a driving current generated by the driving transistor DR. The pixel electrode of the light emitting device ED may be an independent electrode for each light emitting device, and the reflective electrode and the emission layer of the light emitting device ED may be common layers shared by all light emitting devices, but embodiments of the present disclosure are not limited thereto.

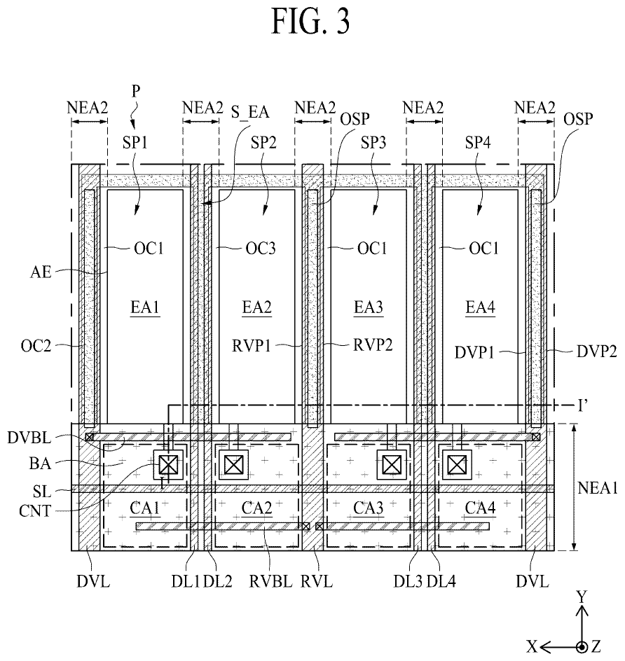

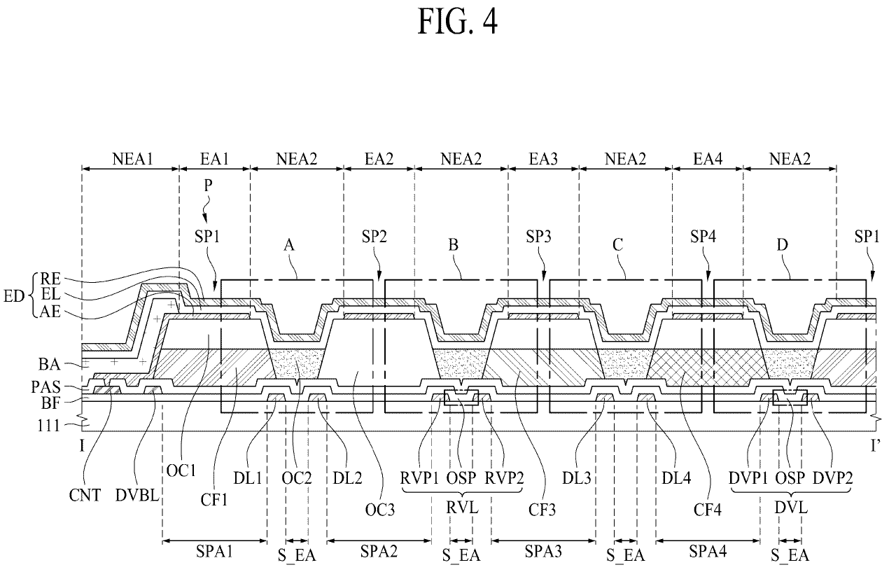

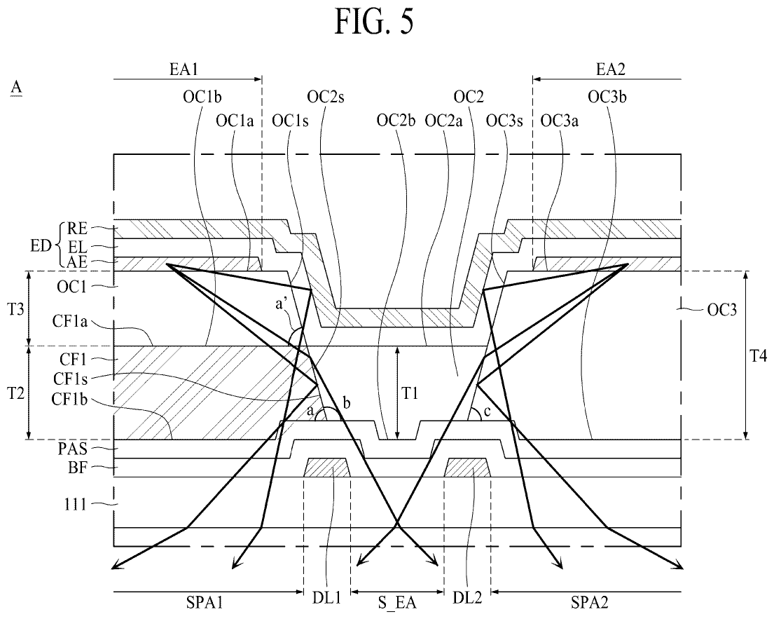

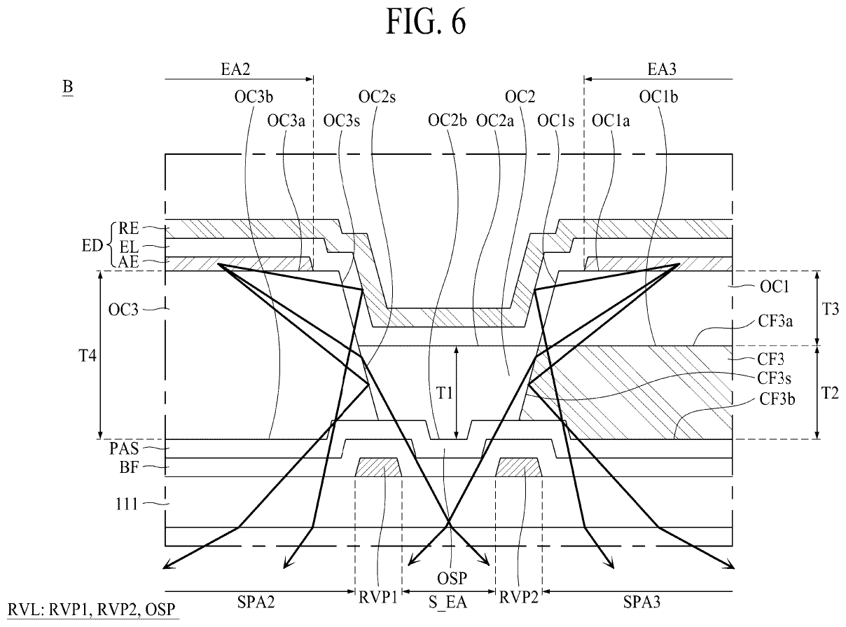

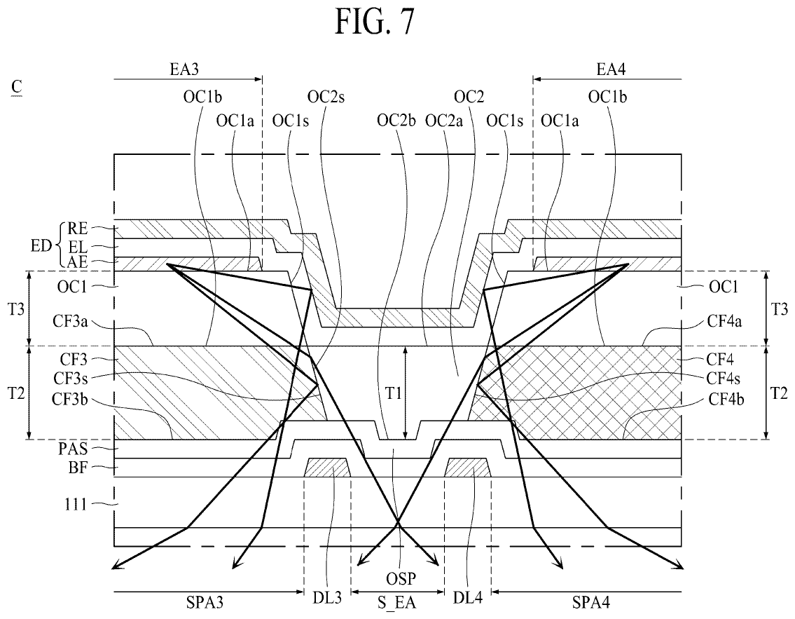

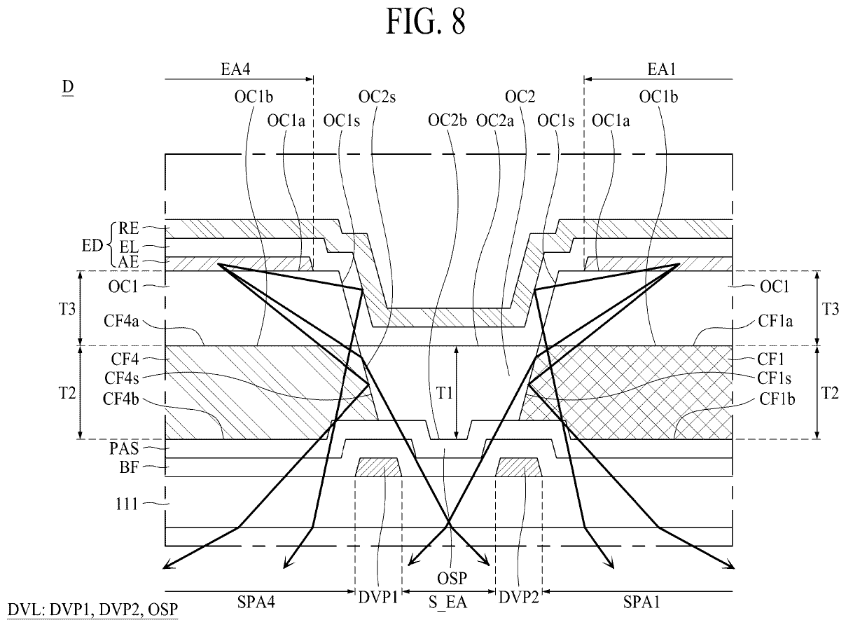

FIG. 3 illustrates a plurality of subpixels in a display panel according to an example embodiment of the present disclosure. FIG. 4 is a cross-sectional view taken along line I-I′ in FIG. 3 according to an example embodiment of the present disclosure. FIG. 5 illustrates an A region shown in FIG. 4 according to an example embodiment of the present disclosure. FIG. 6 illustrates a B region shown in FIG. 4 according to an example embodiment of the present disclosure. FIG. 7 illustrates a C region shown in FIG. 4 according to an example embodiment of the present disclosure. FIG. 8 illustrates a D region shown in FIG. 4 according to an example embodiment of the present disclosure.

As shown in FIGS. 3 to 8, the display panel 110 according to an example embodiment of the present disclosure may be configured as a top-emission type, a bottom-emission type, or a dual-emission type. For example, the display panel 110 may be implemented as the bottom-emission type, but embodiments of the present disclosure are not limited thereto.

The display panel 110 according to an example embodiment of the present disclosure may include a plurality of subpixels SP1, SP2, SP3, and SP4, a plurality of data lines DL1, DL2, DL3, and DL4, at least one scan line SL (or gate line), a first power voltage line DVL, a reference voltage line RVL, a plurality of pixel circuits CA1, CA2, CA3, and CA4, at least one color filter CF1, CF3, and CF4, a first overcoat layer OC1, and a second overcoat layer OC2.

The plurality of subpixels SP1, SP2, SP3, and SP4 may be unit pixels representing different colors. The plurality of subpixels SP1, SP2, SP3, and SP4 may be arranged in a stripe pattern aligned in the first direction (or X-axis direction) or the second direction (or Y-axis direction) intersecting the first direction (or X-axis direction). For example, the plurality of subpixels SP1, SP2, SP3, and SP4 may be arranged in the first direction (or X-axis direction), but embodiments of the present disclosure are not limited thereto, and the arrangement order or layout pattern may be variously modified.

The plurality of subpixels SP1, SP2, SP3, and SP4 may include emission areas EA1, EA2, EA3, and EA4 in which light is emitted by light emitting devices ED each including a pixel electrode AE, an emission layer EL, and a reflective electrode RE (or a common electrode), and a non-emission area NEA. For example, the non-emission area NEA may include a first non-emission area NEA1 in which pixel circuits CA1, CA2, CA3, and CA4 are disposed, and a second non-emission area NEA2 between adjacent subpixels SP1, SP2, SP3, and SP4. For example, the pixel circuits CA1, CA2, CA3, and CA4 of the respective subpixels SP1, SP2, SP3, and SP4 may include at least one thin film transistor DR, TR1, or TR2 and a storage capacitor Cst, but embodiments of the present disclosure are not limited thereto.

The display panel 110 according to an example embodiment of the present disclosure may be implemented as a bottom-emission type, and the emission areas EA1, EA2, EA3, and EA4 of the respective subpixels SP1, SP2, SP3, and SP4 and the first non-emission areas NEA1 in which the pixel circuits CA1, CA2, CA3, and CA4 are disposed may not overlap each other or may overlap at least in part. For example, the emission areas EA1, EA2, EA3, and EA4 may be disposed on an upper side in the second direction (or Y-axis direction), and the first non-emission area NEA1 may be disposed on a lower side in the second direction, but embodiments of the present disclosure are not limited thereto.

In the first non-emission area NEA1, at least one scan line SL extending in the first direction (or X-axis direction) may be disposed, and in the second non-emission area NEA2, at least one voltage signal line extending in the second direction (or Y-axis direction) may be disposed. For example, the at least one voltage signal line may include the plurality of data lines DL1, DL2, DL3, and DL4, the at least one reference voltage line RVL, and the at least one first power voltage line DVL (or driving power voltage line).

The first non-emission area NEA1 may further include a bank portion BA covering edges of the pixel electrodes AE of the respective subpixels SP1, SP2, SP3, and SP4. The bank portion BA may be disposed between the pixel electrodes AE and the emission layers EL of the respective subpixels SP1, SP2, SP3, and SP4. For example, the bank portion BA may be configured to cover contact portions CNT where the pixel electrodes AE of the respective subpixels SP1, SP2, SP3, and SP4 are electrically connected to second nodes N2 (or source electrodes) of driving transistors DR of the respective pixel circuits CA1, CA2, CA3, and CA4. According to an example embodiment of the present disclosure, the second overcoat layer OC2 may be configured to surround remaining outer portions of the respective emission areas EA1, EA2, EA3, and EA4 except for the first non-emission area NEA1 in which the bank portion BA is disposed.

The emission areas EA1, EA2, EA3, and EA4 may correspond to areas in which light is emitted in the respective subpixels SP1, SP2, SP3, and SP4. For example, each of the subpixels SP1, SP2, SP3, and SP4 may include the light emitting device ED formed by overlapping the pixel electrode AE, the emission layer EL, and the reflective electrode RE, and the emission areas EA1, EA2, EA3, and EA4 may correspond to the light emitting devices ED of the respective subpixels SP1, SP2, SP3, and SP4. For example, the emission areas EA1, EA2, EA3, and EA4 may correspond to areas of the pixel electrodes AE patterned and disposed on the first overcoat layer OC1.

The emission areas EA1, EA2, EA3, and EA4 may include first to fourth emission areas EA1, EA2, EA3, and EA4 that emit light of different colors. For example, the emission areas EA1, EA2, EA3, and EA4 may overlap at least one color filter CF1, CF3, and CF4, and thus may emit light of different colors through the color filters.

The at least one color filter CF1, CF3, and CF4 may emit light of different colors. For example, the at least one color filter CF1, CF3, and CF4 may be formed of organic materials that transmit light of different colors. The at least one color filter CF1, CF3, and CF4 may include a first color filter CF1 that transmits red light, a third color filter CF3 that transmits blue light, and a fourth color filter CF4 that transmits green light.

The first emission area EA1 of the first subpixel SP1 may emit red light through the first color filter CF1, the second emission area EA2 of the second subpixel SP2 may emit white light through no color filter or through a color filter that transmits white light, the third emission area EA3 of the third subpixel SP3 may emit blue light through the third color filter CF3, and the fourth emission area EA4 of the fourth subpixel SP4 may emit green light through the fourth color filter CF4, but embodiments of the present disclosure are not limited thereto.

According to an example embodiment of the present disclosure, at least some of the plurality of subpixels SP1, SP2, SP3, and SP4, for example, the subpixels SP1, SP3, and SP4, may include color filters CF1, CF3, and CF4 disposed on a substrate 111 and a first overcoat layer OC1 disposed on the color filters CF1, CF3, and CF4. Also, among the plurality of subpixels SP1, SP2, SP3, and SP4, a second subpixel SP2 may be a white subpixel in which no color filter is disposed, and the second subpixel SP2 may further include a third overcoat layer OC3 disposed on the substrate 111. The third overcoat layer OC3 may be formed of the same material as the first overcoat layer OC1. For example, the third overcoat layer OC3 may have a height corresponding to a height of an overlapped structure of each color filter CF1, CF3, and CF4 and the first overcoat layer OC1, but embodiments of the present disclosure are not limited thereto.

The at least one scan line SL (or gate line) may be disposed to overlap the first non-emission area NEA1 in which the pixel circuits CA1, CA2, CA3, and CA4 are disposed. The at least one scan line SL may extend in the first direction (or X-axis direction) to cross the first non-emission area NEA1. The at least one scan line SL may supply scan signals to at least one thin film transistor TR1 or TR2 included in the pixel circuits CA1, CA2, CA3, and CA4. For example, the at least one scan line SL may be formed of the same material as, and in the same layer as, gate electrodes of the at least one thin film transistor DR, TR1, or TR2 disposed in the pixel circuits CA1, CA2, CA3, and CA4. For example, the at least one scan line SL may include a plurality of scan lines SL configured to apply individual scan signals to first and second switching transistors TR1 and TR2 of the pixel circuits CA1, CA2, CA3, and CA4, but embodiments of the present disclosure are not limited thereto.

The plurality of data lines DL1, DL2, DL3, and DL4 may be disposed to correspond to respective subpixels SP1, SP2, SP3, and SP4. The plurality of data lines DL1, DL2, DL3, and DL4 may be disposed between the plurality of subpixels SP1, SP2, SP3, and SP4. For example, the plurality of data lines DL1, DL2, DL3, and DL4 may be disposed to overlap a second non-emission area NEA2 between adjacent subpixels SP1, SP2, SP3, and SP4. The plurality of data lines DL1, DL2, DL3, and DL4 may extend in the second direction (or Y-axis direction) in the second non-emission area NEA2.

First and second data lines DL1 and DL2 may extend in the second direction (or Y-axis direction) in the second non-emission area NEA2 between the first subpixel SP1 and the second subpixel SP2. The first data line DL1 may be disposed on a right side of the first subpixel SP1 to supply a data voltage to the first subpixel SP1, and the second data line DL2 may be disposed on a left side of the second subpixel SP2 to supply a data voltage to the second subpixel SP2.

The first and second data lines DL1 and DL2 may be spaced apart from each other in the first direction (or X-axis direction) and may extend parallel to each other in the second direction (or Y-axis direction) in the second non-emission area NEA2. The second overcoat layer OC2 may be disposed in a spaced region between the first and second data lines DL1 and DL2. The second overcoat layer OC2 may overlap or may not overlap the first and second data lines DL1 and DL2 in a vertical direction (or Z-axis direction). For example, centers of the first and second data lines DL1 and DL2 may overlap the second overcoat layer OC2 in the vertical direction.

Third and fourth data lines DL3 and DL4 may extend in the second direction (or Y-axis direction) in the second non-emission area NEA2 between the third subpixel SP3 and the fourth subpixel SP4. The third data line DL3 may be disposed on a right side of the third subpixel SP3 to supply a data voltage to the third subpixel SP3, and the fourth data line DL4 may be disposed on a left side of the fourth subpixel SP4 to supply a data voltage to the fourth subpixel SP4.

The third and fourth data lines DL3 and DL4 may be spaced apart from each other in the first direction (or X-axis direction) and may extend parallel to each other in the second direction (or Y-axis direction) in the second non-emission area NEA2. A spaced region between the third and fourth data lines DL3 and DL4 may include the second overcoat layer OC2. The second overcoat layer OC2 may overlap or may not overlap the third and fourth data lines DL3 and DL4 in the vertical direction (or Z-axis direction). For example, centers of the third and fourth data lines DL3 and DL4 may overlap the second overcoat layer OC2 in the vertical direction.

According to an example embodiment of the present disclosure, the second non-emission area NEA2 between adjacent subpixels SP1, SP2, SP3, and SP4 may further include an auxiliary emission area S_EA that does not overlap the plurality of data lines DL1, DL2, DL3, and DL4. For example, the auxiliary emission area S_EA may be formed between the first data line DL1 and the second data line DL2 in the second non-emission area NEA2 between the adjacent first and second subpixels SP1 and SP2. In addition, the auxiliary emission area S_EA may be formed between the third data line DL3 and the fourth data line DL4 in the second non-emission area NEA2 between the adjacent third and fourth subpixels SP3 and SP4.

The at least one first power voltage line DVL (or driving power voltage line) may be disposed to correspond to the plurality of subpixels SP1, SP2, SP3, and SP4. The at least one first power voltage line DVL may be disposed on a left side or a right side of the plurality of subpixels SP1, SP2, SP3, and SP4. For example, the at least one first power voltage line DVL may be disposed on a left side of the first subpixel SP1 and may be disposed to overlap the second non-emission area NEA2 between the first subpixel SP1 and a fourth subpixel SP4 of another adjacent pixel P. In addition, the at least one first power voltage line DVL may be disposed on a right side of the fourth subpixel SP4 and may be disposed to overlap the second non-emission area NEA2 between the fourth subpixel SP4 and a first subpixel SP1 of another adjacent pixel P. The at least one first power voltage line DVL may extend in the second direction (or Y-axis direction) in the second non-emission area NEA2 between adjacent pixels P. The at least one first power voltage line DVL may supply a first power voltage EVDD to the respective subpixels SP1, SP2, SP3, and SP4 through a first power voltage bridge line DVBL extending in the first direction (or X-axis direction).

The first power voltage bridge line DVBL may extend rightward from the at least one first power voltage line DVL disposed on a left side of the plurality of subpixels SP1, SP2, SP3, and SP4 to supply the first power voltage EVDD to the first and second subpixels SP1 and SP2. In addition, the first power voltage bridge line DVBL may extend leftward from the at least one first power voltage line DVL disposed on a right side of the plurality of subpixels SP1, SP2, SP3, and SP4 to supply the first power voltage EVDD to the third and fourth subpixels SP3 and SP4, but embodiments of the present disclosure are not limited thereto.

According to an example embodiment of the present disclosure, the at least one first power voltage line DVL may have a width greater than each of widths of the respective data lines DL1, DL2, DL3, and DL4. For example, the at least one first power voltage line DVL may have a width greater than widths of at least two data lines.

The at least one first power voltage line DVL may further include an opening slit pattern OSP extending in the second direction from a center in a widthwise direction. The opening slit pattern OSP may be formed in a portion of the at least one first power voltage line DVL. For example, the opening slit pattern OSP may be formed at portions where the emission areas EA1, EA2, EA3, and EA4 of the respective subpixels SP1, SP2, SP3, and SP4 are located.

The at least one first power voltage line DVL may be divided into a first portion DVP1 and a second portion DVP2 between adjacent pixels P by the opening slit pattern OSP. For example, the at least one first power voltage line DVL may be divided into the first portion DVP1 adjacent to the fourth subpixel SP4 of another pixel P and the second portion DVP2 adjacent to the first subpixel SP1, or may be divided into the first portion DVP1 adjacent to the fourth subpixel SP4 and the second portion DVP2 adjacent to the first subpixel SP1 of another pixel P.

The first and second portions DVP1 and DVP2 of the at least one first power voltage line DVL may be spaced apart from each other in the first direction (or X-axis direction) and may extend parallel to each other in the second direction (or Y-axis direction). In addition, the opening slit pattern OSP may be disposed between the first and second portions DVP1 and DVP2 of the at least one first power voltage line DVL.

The second overcoat layer OC2 may be disposed in the opening slit pattern OSP of the at least one first power voltage line DVL. The second overcoat layer OC2 may overlap or may not overlap the first and second portions DVP1 and DVP2 of the at least one first power voltage line DVL in the vertical direction (or Z-axis direction). For example, centers of the first and second portions DVP1 and DVP2 of the at least one first power voltage line DVL may overlap the second overcoat layer OC2 in the vertical direction.

According to an example embodiment of the present disclosure, the second non-emission area NEA2 between adjacent pixels P may further include an auxiliary emission area S_EA that does not overlap the first and second portions DVP1 and DVP2 of the at least one first power voltage line DVL. The auxiliary emission area S_EA may be configured to overlap the opening slit pattern OSP of the at least one first power voltage line DVL in the second non-emission area NEA2 between adjacent pixels P. For example, the auxiliary emission area S_EA may be formed between the first and second portions DVP1 and DVP2 of the at least one first power voltage line DVL.

The reference voltage line RVL may be disposed to correspond to the plurality of subpixels SP1, SP2, SP3, and SP4. The reference voltage line RVL may be disposed within the plurality of subpixels SP1, SP2, SP3, and SP4. The reference voltage line RVL may be disposed between the second subpixel SP2 and the third subpixel SP3. The reference voltage line RVL may extend in the second direction (or Y-axis direction) in the second non-emission area NEA2 between the second subpixel SP2 and the third subpixel SP3. The reference voltage line RVL may supply the reference voltage Vref to the respective subpixels SP1, SP2, SP3, and SP4 through a reference voltage bridge line RVBL extending in the first direction (or X-axis direction).

The reference voltage bridge line RVBL may extend to left and right from the reference voltage line RVL, the reference voltage bridge line RVBL extending to the left may supply the reference voltage Vref to the first and second subpixels SP1 and SP2, and the reference voltage bridge line RVBL extending to the right may supply the reference voltage Vref to the third and fourth subpixels SP3 and SP4, but embodiments of the present disclosure are not limited thereto.

According to an example embodiment of the present disclosure, the reference voltage line RVL may have a width greater than each of widths of the respective data lines DL1, DL2, DL3, and DL4. For example, the reference voltage line RVL may have a width greater than widths of at least two data lines.

The reference voltage line RVL may further include an opening slit pattern OSP extending in the second direction from a center in a widthwise direction. The opening slit pattern OSP may be formed in a portion of the reference voltage line RVL. For example, the opening slit pattern OSP may be formed at portions where the emission areas EA1, EA2, EA3, and EA4 of the respective subpixels SP1, SP2, SP3, and SP4 are located.

The reference voltage line RVL may be divided into a first portion RVP1 and a second portion RVP2 between the adjacent second and third subpixels SP2 and SP3 by the opening slit pattern OSP. For example, the reference voltage line RVL may be divided into the first portion RVP1 adjacent to the second subpixel SP2 and the second portion RVP2 adjacent to the third subpixel SP3.

The first and second portions RVP1 and RVP2 of the reference voltage line RVL may be spaced apart from each other in the first direction (or X-axis direction) and may extend parallel to each other in the second direction (or Y-axis direction). In addition, the opening slit pattern OSP may be disposed between the first and second portions RVP1 and RVP2 of the reference voltage line RVL.

The second overcoat layer OC2 may be disposed in the opening slit pattern OSP of the reference voltage line RVL. The second overcoat layer OC2 may overlap or may not overlap the first and second portions RVP1 and RVP2 of the reference voltage line RVL in the vertical direction (or Z-axis direction). For example, centers of the first and second portions RVP1 and RVP2 of the reference voltage line RVL may overlap the second overcoat layer OC2 in the vertical direction.

According to an example embodiment of the present disclosure, the second non-emission area NEA2 between the second subpixel SP2 and the third subpixel SP3 may further include an auxiliary emission area S_EA that does not overlap the first and second portions RVP1 and RVP2 of the reference voltage line RVL. The auxiliary emission area S_EA may be configured to overlap the opening slit pattern OSP of the reference voltage line RVL in the second non-emission area NEA2 between the second subpixel SP2 and the third subpixel SP3. For example, the auxiliary emission area S_EA may be formed between the first and second portions RVP1 and RVP2 of the reference voltage line RVL.

As shown in FIGS. 4 to 8, the display panel 110 according to an example embodiment of the present disclosure may include a substrate 111, the plurality of data lines DL1, DL2, DL3, and DL4, the at least one first power voltage line DVL, the reference voltage line RVL, at least one insulating layer BF and PAS, the at least one color filter CF1, CF3, and CF4, the first overcoat layer OC1, the second overcoat layer OC2, the third overcoat layer OC3, the pixel electrode AE, the emission layer EL, and the reflective electrode RE. For example, the display panel 110 may further include the bank portion BA disposed between the pixel electrode AE and the emission layer EL in the first non-emission area NEA1.

At least one voltage signal line may be disposed on the substrate 111. For example, the plurality of data lines DL1, DL2, DL3, and DL4, the at least one first power voltage line DVL, and the reference voltage line RVL may be disposed on the substrate 111. For example, the plurality of data lines DL1, DL2, DL3, and DL4, the at least one first power voltage line DVL, and the reference voltage line RVL may be formed of the same material and in the same layer as a light-shielding layer disposed in the pixel circuits CA1, CA2, CA3, and CA4, but embodiments of the present disclosure are not limited thereto.

As shown in FIGS. 4 and 5, among the plurality of data lines DL1, DL2, DL3, and DL4, the first and second data lines DL1 and DL2 may be disposed in the second non-emission area NEA2 between the first subpixel SP1 and the second subpixel SP2. The first data line DL1 may be adjacent to the first subpixel SP1, and the second data line DL2 may be adjacent to the second subpixel SP2, and the first and second data lines DL1 and DL2 may be spaced apart by a predetermined interval. The auxiliary emission area S_EA may be disposed in a spaced region between the first and second data lines DL1 and DL2. The auxiliary emission area S_EA may overlap the second overcoat layer OC2 between the first and second data lines DL1 and DL2.

As shown in FIGS. 4 and 7, among the plurality of data lines DL1, DL2, DL3, and DL4, the third and fourth data lines DL3 and DL4 may be disposed in the second non-emission area NEA2 between the third subpixel SP3 and the fourth subpixel SP4. The third data line DL3 may be adjacent to the third subpixel SP3, the fourth data line DL4 may be adjacent to the fourth subpixel SP4, and the third and fourth data lines DL3 and DL4 may be spaced apart by a predetermined interval. The auxiliary emission area S_EA may be disposed in a spaced region between the third and fourth data lines DL3 and DL4. The auxiliary emission area S_EA may overlap the second overcoat layer OC2 between the third and fourth data lines DL3 and DL4.

As shown in FIGS. 4 and 8, the at least one first power voltage line DVL may be disposed in the second non-emission area NEA2 located on a left side of the first subpixel SP1 and in the second non-emission area NEA2 located on a right side of the fourth subpixel SP4. For example, the at least one first power voltage line DVL may be disposed in the second non-emission area NEA2 between the fourth subpixel SP4 and the first subpixel SP1 of an adjacent pixel P.

The at least one first power voltage line DVL may further include the opening slit pattern OSP penetrating an upper surface and a lower surface of the at least one first power voltage line DVL from a center in a widthwise direction. The at least one first power voltage line DVL may include the first portion DVP1 and the second portion DVP2 spaced apart from each other with the opening slit pattern OSP interposed therebetween. The first portion DVP1 and the second portion DVP2 of the at least one first power voltage line DVL may be spaced apart by a predetermined interval. For example, the auxiliary emission area S_EA may be disposed in a spaced region between the first portion DVP1 and the second portion DVP2 of the first power voltage line DVL. The auxiliary emission area S_EA may overlap the second overcoat layer OC2 between the first portion DVP1 and the second portion DVP2 of the first power voltage line DVL.

As shown in FIGS. 4 and 6, the reference voltage line RVL may be disposed in the second non-emission area NEA2 between the second subpixel SP2 and the third subpixel SP3. The reference voltage line RVL may further include the opening slit pattern OSP penetrating an upper surface and a lower surface of the reference voltage line RVL from a center in a widthwise direction. The reference voltage line RVL may include the first portion RVP1 and the second portion RVP2 spaced apart from each other with the opening slit pattern OSP interposed therebetween. The first portion RVP1 of the reference voltage line RVL may be adjacent to the second subpixel SP2, the second portion RVP2 of the reference voltage line RVL may be adjacent to the third subpixel SP3, and the first and second portions RVP1 and RVP2 of the reference voltage line RVL may be spaced apart by a predetermined interval. For example, the auxiliary emission area S_EA may be disposed in a spaced region between the first portion RVP1 and the second portion RVP2 of the reference voltage line RVL. The auxiliary emission area S_EA may overlap the second overcoat layer OC2 between the first portion RVP1 and the second portion RVP2 of the reference voltage line RVL.

The at least one insulating layer BF and PAS may be disposed on the substrate 111. The at least one insulating layer BF and PAS may be disposed on the pixel circuits CA1, CA2, CA3, and CA4, and may include a buffer layer BF and a passivation layer PAS. For example, the buffer layer BF may be disposed on the substrate 111. The buffer layer BF may be configured to cover at least one voltage signal line and a light-shielding layer on the substrate 111. At least one thin film transistor and the passivation layer PAS may be disposed on the buffer layer BF. For example, between the buffer layer BF and the passivation layer PAS, a gate insulating layer and an interlayer insulating layer interposed between, or covering, an active layer, a gate electrode, and source/drain electrodes of the at least one thin film transistor may further be included, but embodiments of the present disclosure are not limited thereto. For example, the at least one insulating layer BF and PAS may be formed as a single layer or multilayer including inorganic insulating materials such as silicon oxide SiO_{X}, silicon nitride SiN_{X}, and aluminum oxide Al₂O₃, but embodiments of the present disclosure are not limited thereto.

The at least one color filter CF1, CF3, and CF4 may be disposed on the at least one insulating layer BF and PAS. For example, the at least one color filter CF1, CF3, and CF4 may be disposed on the passivation layer PAS. The at least one color filter CF1, CF3, and CF4 may be disposed to correspond to the first, third, and fourth subpixels SP1, SP3, and SP4 among the first to fourth subpixels SP1, SP2, SP3, and SP4. A color filter may not be disposed in the second subpixel SP2 among the first to fourth subpixels. For example, the third overcoat layer OC3 may be disposed on the passivation layer PAS corresponding to the second subpixel SP2.

According to an example embodiment of the present disclosure, on a rear surface of the substrate 111, a plurality of subpixel areas SPA1, SPA2, SPA3, and SPA4 may be disposed. The plurality of subpixel areas SPA1, SPA2, SPA3, and SPA4 may include at least portions of the emission areas EA1, EA2, EA3, and EA4 and the second non-emission area NEA2. Each subpixel area SPA1, SPA2, SPA3, and SPA4 may be an area through which light is emitted via the rear surface of the substrate 111. For example, each subpixel area SPA1, SPA2, SPA3, and SPA4 may be an area in which light emitted from the emission areas EA1, EA2, EA3, and EA4 is actually emitted through the rear surface of the substrate 111.

Each subpixel area SPA1, SPA2, SPA3, and SPA4 may be an area not overlapping at least one voltage signal line. For example, the first subpixel area SPA1 may be an area between the first power voltage line DVL and the first data line DL1, the second subpixel area SPA2 may be an area between the second data line DL2 and the reference voltage line RVL, the third subpixel area SPA3 may be an area between the reference voltage line RVL and the third data line DL3, and the fourth subpixel area SPA4 may be an area between the fourth data line DL4 and the first power voltage line DVL.

The first color filter CF1 that converts white light emitted from the first emission area EA1 into red light may be disposed in the first subpixel area SPA1 of the first subpixel SP1. No color filter is disposed in the second subpixel area SPA2 of the second subpixel SP2, and a third overcoat layer OC3 that allows white light emitted from the second emission area EA2 to be emitted as is may be disposed therein. The third color filter CF3 that converts white light emitted from the third emission area EA3 into blue light may be disposed in the third subpixel area SPA3 of the third subpixel SP3. The fourth color filter CF4 that converts white light emitted from the fourth emission area EA4 into green light may be disposed in the fourth subpixel area SPA4 of the fourth subpixel SP4.

The at least one color filter CF1, CF3, and CF4 and the third overcoat layer OC3 may be disposed to overlap the corresponding emission areas EA1, EA2, EA3, and EA4. The at least one color filter CF1, CF3, and CF4 and the third overcoat layer OC3 may have sizes greater than the corresponding emission areas EA1, EA2, EA3, and EA4. For example, both edge portions of each of the at least one color filter CF1, CF3, and CF4 and the third overcoat layer OC3 may overlap the second non-emission area NEA2.

On the at least one insulating layer BF and PAS, the second overcoat layer OC2 may be disposed between adjacent subpixels SP1, SP2, SP3, and SP4 or between adjacent color filters. The second overcoat layer OC2 may be disposed to overlap the second non-emission area NEA2. For example, the second overcoat layer OC2 may be disposed on the passivation layer PAS. The second overcoat layer OC2 may be disposed, on the passivation layer PAS, between color filters that are adjacent to each other among the at least one color filter CF1, CF3, and CF4 and the third overcoat layer OC3, or between an adjacent color filter and the third overcoat layer OC3.

As shown in FIGS. 4 and 5, between the first and second subpixels SP1 and SP2, the second overcoat layer OC2 may be disposed on the passivation layer PAS between the first color filter CF1 and the third overcoat layer OC3, and may contact a side surface of the first color filter CF1 and a portion of a side surface of the third overcoat layer OC3. For example, the first color filter CF1 may have an upper surface CF1a width smaller than a lower surface CF1b width and may include a slope surface CF1s with a positive taper on a side surface. In addition, the third overcoat layer OC3 may have an upper surface OC3a width smaller than a lower surface OC3b width and may include a slope surface OC3s with a positive taper on a side surface. For example, the slope surface CF1s of the first color filter CF1 and the slope surface OC3s of the third overcoat layer OC3 may have equal slope angles a and c within a range of process tolerance, but embodiments of the present disclosure are not limited thereto.

The second overcoat layer OC2 may have an upper surface OC2a width greater than a lower surface OC2b width and may include a slope surface OC2s with a negative taper on a side surface. The second overcoat layer OC2 may contact portions of the slope surface CF1s of the first color filter CF1 and the slope surface OC3s of the third overcoat layer OC3. For example, the slope surface OC2s of the second overcoat layer OC2 may face the slope surface CF1s of the first color filter CF1, which may have corresponding slope angles b and a. In addition, the slope surface OC2s of the second overcoat layer OC2 may face the slope surface OC3s of the third overcoat layer OC3, which may have corresponding slope angles b and c, but embodiments of the present disclosure are not limited thereto.

The second overcoat layer OC2 may overlap or may not overlap the first and second data lines DL1 and DL2 in the vertical direction (or Z-axis direction) of the substrate 111. For example, the second overcoat layer OC2 may be disposed to overlap centers of the first and second data lines DL1 and DL2 in the vertical direction. According to an example embodiment of the present disclosure, the second overcoat layer OC2 may include the auxiliary emission area S_EA disposed in a portion not overlapping the first and second data lines DL1 and DL2. For example, the auxiliary emission area S_EA may be formed between the first and second data lines DL1 and DL2 in the second overcoat layer OC2.

The second overcoat layer OC2 may have a height equal to or different from that of the first color filter CF1. For example, the second overcoat layer OC2 may have a first height T1 from the passivation layer PAS, and the first color filter CF1 may have a second height T2 from the passivation layer PAS. The first height T1 of the second overcoat layer OC2 and the second height T2 of the first color filter CF1 may be equal within a range of process tolerance, but embodiments of the present disclosure are not limited thereto.

The second overcoat layer OC2 may have a refractive index different from that of the first color filter CF1. In addition, the second overcoat layer OC2 may have a refractive index different from that of the third overcoat layer OC3. For example, the second overcoat layer OC2 may have a refractive index smaller than that of each of the first color filter CF1 and the third overcoat layer OC3.

The first overcoat layer OC1 may be disposed on the first color filter CF1. For example, the first color filter CF1 and the first overcoat layer OC1 may overlap the first emission area EA1. In addition, the third overcoat layer OC3 may be formed of the same material as the first overcoat layer OC1. The third overcoat layer OC3 may overlap the second emission area EA2.

The first overcoat layer OC1 may have an upper surface OC1a width smaller than a lower surface OC1b width and may include a slope surface OC1s with a positive taper on a side surface. For example, the slope surface OC1s of the first overcoat layer OC1 may have a slope angle equal to that of the slope surface CF1s of the first color filter CF1 within a range of process tolerance (a′, a). In addition, the slope surface OC1s of the first overcoat layer OC1 may have a slope angle equal to that of the slope surface OC3s of the third overcoat layer OC3 within a range of process tolerance (a′, c), but embodiments of the present disclosure are not limited thereto.

An overlapped height of the first overcoat layer OC1 with the first color filter CF1 may be equal to or different from a height of the third overcoat layer OC3. For example, the first overcoat layer OC1 may have a third height T3 from the first color filter CF1, and the third overcoat layer OC3 may have a fourth height T4 from the passivation layer PAS. An overlapped height T2+T3 of the first overcoat layer OC1 and the first color filter CF1 may be equal to the height T4 of the third overcoat layer OC3 within a range of process tolerance, but embodiments of the present disclosure are not limited thereto.

The first overcoat layer OC1 and the third overcoat layer OC3 may each have refractive indices higher than that of the second overcoat layer OC2. In addition, the second overcoat layer OC2 may have a refractive index lower than that of the first color filter CF1. For example, a difference in refractive index between the first color filter CF1 and the first overcoat layer OC1 may be smaller than a difference in refractive index between the first color filter CF1 and the second overcoat layer OC2. Accordingly, a portion of light emitted from the first and second emission areas EA1 and EA2 may form additional light-extraction paths through total internal reflection at an interface between the first color filter CF1 and the second overcoat layer OC2 or at an interface between the third overcoat layer OC3 and the second overcoat layer OC2 due to the refractive-index differences. For example, the second overcoat layer OC2 may totally reflect light, among light emitted from the first and second emission areas EA1 and EA2, that travels toward other adjacent subpixels SP1 and SP2 so that the light may be re-emitted through the corresponding subpixel areas SPA1 and SPA2. In addition, the second overcoat layer OC2 may change a path of light, among light emitted from the first and second emission areas EA1 and EA2, that travels toward other adjacent subpixels SP1 and SP2 so that the light may be emitted through the auxiliary emission area S_EA in the second overcoat layer OC2.

The auxiliary emission area S_EA between the first and second subpixels SP1 and SP2 may emit light having a color corresponding to the first subpixel SP1, a color corresponding to the second subpixel SP2, or a color different from colors of the first and second subpixels SP1 and SP2. For example, the auxiliary emission area S_EA may emit red light corresponding to the first color filter CF1 of the first subpixel SP1.

As shown in FIG. 6, in describing the configuration between the second and third subpixels SP2 and SP3, the same reference numerals are assigned to the configurations described with reference to FIGS. 4 and 5, and duplicate descriptions thereof are omitted or briefly given.

As shown in FIG. 6, between the second and third subpixels SP2 and SP3, the second overcoat layer OC2 may be disposed on the passivation layer PAS between the third overcoat layer OC3 and the third color filter CF3, and may contact a portion of a side surface of the third overcoat layer OC3 and a side surface of the third color filter CF3. For example, the third color filter CF3 may have an upper surface CF3a width smaller than a lower surface CF3b width and may include a slope surface CF3s with a positive taper on a side surface. For example, the slope surface CF3s of the third color filter CF3 and the slope surface OC3s of the third overcoat layer OC3 may have equal slope angles a and c within a range of process tolerance, but embodiments of the present disclosure are not limited thereto.

The second overcoat layer OC2 may contact the slope surface CF3s of the third color filter CF3 and the slope surface OC3s of the third overcoat layer OC3. For example, the slope surface OC2s of the second overcoat layer OC2 may face the slope surface CF3s of the third color filter CF3, which may have corresponding slope angles b and a, but embodiments of the present disclosure are not limited thereto.

The second overcoat layer OC2 may overlap or may not overlap the first portion RVP1 and the second portion RVP2 of the reference voltage line RVL in the vertical direction (or Z-axis direction) of the substrate 111. For example, the second overcoat layer OC2 may be disposed to overlap or not overlap centers of the first portion RVP1 and the second portion RVP2 of the reference voltage line RVL in the vertical direction. According to an example embodiment of the present disclosure, the second overcoat layer OC2 may include the auxiliary emission area S_EA disposed in a portion not overlapping the first portion RVP1 and the second portion RVP2 of the reference voltage line RVL. For example, the auxiliary emission area S_EA may be formed between the first portion RVP1 and the second portion RVP2 of the reference voltage line RVL in the second overcoat layer OC2.

The second overcoat layer OC2 may have a height equal to or different from that of the third color filter CF3. For example, the second overcoat layer OC2 may have the first height T1 from the passivation layer PAS, and the third color filter CF3 may have the second height T2 from the passivation layer PAS. The first height T1 of the second overcoat layer OC2 and the second height T2 of the third color filter CF3 may be equal within a range of process tolerance, but embodiments of the present disclosure are not limited thereto.

The second overcoat layer OC2 may have a refractive index different from that of the third color filter CF3. For example, the second overcoat layer OC2 may have a refractive index smaller than each of those of the third color filter CF3 and the third overcoat layer OC3.

The first overcoat layer OC1 may be disposed on the third color filter CF3. For example, the third color filter CF3 and the first overcoat layer OC1 may overlap the third emission area EA3. For example, the slope surface OC1s of the first overcoat layer OC1 may have a slope angle equal to that of the slope surface CF3s of the third color filter CF3 within a range of process tolerance (a′, a), but embodiments of the present disclosure are not limited thereto.

An overlapped height of the first overcoat layer OC1 with the third color filter CF3 may be equal to or different from a height of the third overcoat layer OC3. For example, the first overcoat layer OC1 may have the third height T3 from the third color filter CF3, and the third overcoat layer OC3 may have the fourth height T4 from the passivation layer PAS. An overlapped height T2+T3 of the first overcoat layer OC1 and the third color filter CF3 may be equal to the height T4 of the third overcoat layer OC3 within a range of process tolerance, but embodiments of the present disclosure are not limited thereto.

The second overcoat layer OC2 may have a refractive index lower than that of the third color filter CF3. For example, a difference in refractive index between the third color filter CF3 and the first overcoat layer OC1 may be smaller than a difference in refractive index between the third color filter CF3 and the second overcoat layer OC2. Accordingly, a portion of light emitted from the second and third emission areas EA2 and EA3 may form additional light-extraction paths through total internal reflection at an interface between the third color filter CF3 and the second overcoat layer OC2 or at an interface between the third overcoat layer OC3 and the second overcoat layer OC2 due to the refractive-index differences. For example, the second overcoat layer OC2 may totally reflect light, among light emitted from the second and third emission areas EA2 and EA3, that travels toward other adjacent subpixels SP2 and SP3 so that the light may be re-emitted through the corresponding subpixel areas SPA2 and SPA3. In addition, the second overcoat layer OC2 may change a path of light, among light emitted from the second and third emission areas EA2 and EA3, that travels toward other adjacent subpixels SP2 and SP3 so that the light may be emitted through the auxiliary emission area S_EA in the second overcoat layer OC2.

The auxiliary emission area S_EA between the second and third subpixels SP2 and SP3 may emit light having a color corresponding to the second subpixel SP2, a color corresponding to the third subpixel SP3, or a color different from colors of the second and third subpixels SP2 and SP3. For example, the auxiliary emission area S_EA may emit blue light corresponding to the third color filter CF3 of the third subpixel SP3.

As shown in FIG. 7, in describing the configuration between the third and fourth subpixels SP3 and SP4, the same reference numerals are assigned to the configurations described with reference to FIGS. 4 to 6, and duplicate descriptions thereof are omitted or briefly given.

As shown in FIG. 7, between the third and fourth subpixels SP3 and SP4, the second overcoat layer OC2 may be disposed on the passivation layer PAS between the third color filter CF3 and the fourth color filter CF4, and may contact side surfaces of the third color filter CF3 and the fourth color filter CF4. For example, the fourth color filter CF4 may have an upper surface CF4a width smaller than a lower surface CF4b width and may include a slope surface CF4s with a positive taper on a side surface. For example, the slope surface CF4s of the fourth color filter CF4 and the slope surface CF3s of the third color filter CF3 may have equal slope angles a within a range of process tolerance, but embodiments of the present disclosure are not limited thereto.

The second overcoat layer OC2 may contact the slope surface CF3s of the third color filter CF3 and the slope surface CF4s of the fourth color filter CF4. For example, the slope surface OC2s of the second overcoat layer OC2 may face the slope surface CF4s of the fourth color filter CF4, which may have corresponding slope angles b and a, but embodiments of the present disclosure are not limited thereto.

The second overcoat layer OC2 may overlap or may not overlap the third and fourth data lines DL3 and DL4 in the vertical direction of the substrate 111. For example, the second overcoat layer OC2 may be disposed to overlap centers of the third and fourth data lines DL3 and DL4 in the vertical direction. According to an example embodiment of the present disclosure, the second overcoat layer OC2 may include the auxiliary emission area S_EA disposed in a portion not overlapping the third and fourth data lines DL3 and DL4. For example, the auxiliary emission area S_EA may be formed between the third and fourth data lines DL3 and DL4 in the second overcoat layer OC2.

The second overcoat layer OC2 may have a height equal to or different from that of the fourth color filter CF4. For example, the second overcoat layer OC2 may have the first height T1 from the passivation layer PAS, and the fourth color filter CF4 may have the second height T2 from the passivation layer PAS. The first height T1 of the second overcoat layer OC2 and the second height T2 of the fourth color filter CF4 may be equal within a range of process tolerance, but embodiments of the present disclosure are not limited thereto.

The second overcoat layer OC2 may have a refractive index different from that of the fourth color filter CF4. For example, the second overcoat layer OC2 may have a refractive index smaller than each of those of the fourth color filter CF4 and the third color filter CF3.

The first overcoat layer OC1 may be disposed on the fourth color filter CF4. For example, the fourth color filter CF4 and the first overcoat layer OC1 may overlap the fourth emission area EA4. For example, the slope surface OC1s of the first overcoat layer OC1 may have a slope angle equal to that of the slope surface CF4s of the fourth color filter CF4 within a range of process tolerance (a′, a), but embodiments of the present disclosure are not limited thereto.

An overlapped height of the first overcoat layer OC1 with the fourth color filter CF4 may be equal to or different from an overlapped height of the first overcoat layer OC1 with the third color filter CF3. For example, the overlapped height of the first overcoat layer OC1 with the fourth color filter CF4 and the overlapped height of the first overcoat layer OC1 with the third color filter CF3 may be equal within a range of process tolerance, but embodiments of the present disclosure are not limited thereto.

The second overcoat layer OC2 may have a refractive index lower than that of the fourth color filter CF4. For example, a difference in refractive index between the fourth color filter CF4 and the first overcoat layer OC1 may be smaller than a difference in refractive index between the fourth color filter CF4 and the second overcoat layer OC2. Accordingly, a portion of light emitted from the third and fourth emission areas EA3 and EA4 may form additional light-extraction paths through total internal reflection at an interface between the third color filter CF3 and the second overcoat layer OC2 or at an interface between the fourth color filter CF4 and the second overcoat layer OC2 due to the refractive-index differences. For example, the second overcoat layer OC2 may totally reflect light, among light emitted from the third and fourth emission areas EA3 and EA4, that travels toward other adjacent subpixels SP3 and SP4 so that the light may be re-emitted through the corresponding subpixel areas SPA3 and SPA4. In addition, the second overcoat layer OC2 may change a path of light, among light emitted from the third and fourth emission areas EA3 and EA4, that travels toward other adjacent subpixels SP3 and SP4 so that the light may be emitted through the auxiliary emission area S_EA in the second overcoat layer OC2.

The auxiliary emission area S_EA between the third and fourth subpixels SP3 and SP4 may emit light having a color corresponding to the third subpixel SP3, a color corresponding to the fourth subpixel SP4, or a color different from colors of the third and fourth subpixels SP3 and SP4. For example, the auxiliary emission area S_EA may emit cyan light in which blue light corresponding to the third color filter CF3 of the third subpixel SP3 and green light corresponding to the fourth color filter CF4 of the fourth subpixel SP4 are mixed with each other.

As shown in FIG. 8, in describing the configuration between the fourth subpixel SP4 and the first subpixel SP1 of another pixel P, the same reference numerals are assigned to the configurations described with reference to FIGS. 4 to 7, and duplicate descriptions thereof are omitted or briefly given.

As shown in FIG. 8, between the fourth subpixel SP4 and the first subpixel SP1 of another pixel P, the second overcoat layer OC2 may be disposed on the passivation layer PAS between the fourth color filter CF4 and the first color filter CF1, and may contact side surfaces of the fourth color filter CF4 and the first color filter CF1.

The second overcoat layer OC2 may overlap or may not overlap the first portion DVP1 and the second portion DVP2 of the first power voltage line DVL in the vertical direction of the substrate 111. For example, the second overcoat layer OC2 may be disposed to overlap centers of the first portion DVP1 and the second portion DVP2 of the first power voltage line DVL in the vertical direction. According to an example embodiment of the present disclosure, the second overcoat layer OC2 may include the auxiliary emission area S_EA disposed in a portion not overlapping the first portion DVP1 and the second portion DVP2 of the first power voltage line DVL. For example, the auxiliary emission area S_EA may be formed between the first portion DVP1 and the second portion DVP2 of the first power voltage line DVL in the second overcoat layer OC2.

According to an example embodiment of the present disclosure, a portion of light emitted from the first and fourth emission areas EA1 and EA4 may form additional light-extraction paths through total internal reflection at an interface between the first color filter CF1 and the second overcoat layer OC2 or at an interface between the fourth color filter CF4 and the second overcoat layer OC2 due to the refractive-index differences. For example, the second overcoat layer OC2 may totally reflect light, among light emitted from the first and fourth emission areas EA1 and EA4, that travels toward other adjacent subpixels SP1 and SP4 so that the light may be re-emitted through the corresponding subpixel areas SPA1 and SPA4. In addition, the second overcoat layer OC2 may change a path of light, among light emitted from the first and fourth emission areas EA1 and EA4, that travels toward other adjacent subpixels SP1 and SP4 so that the light may be emitted through the auxiliary emission area S_EA in the second overcoat layer OC2.

The auxiliary emission area S_EA between the first and fourth subpixels SP1 and SP4 may emit light having a color corresponding to the first subpixel SP1, a color corresponding to the fourth subpixel SP4, or a color different from colors of the first and fourth subpixels SP1 and SP4. For example, the auxiliary emission area S_EA may emit yellow light in which red light corresponding to the first color filter CF1 of the first subpixel SP1 and green light corresponding to the fourth color filter CF4 of the fourth subpixel SP4 are mixed with each other.

As shown in FIGS. 4 to 8, on the first overcoat layer OC1 and the third overcoat layer OC3, the pixel electrode AE (first electrode or anode electrode), the emission layer EL (or organic emission layer), and the reflective electrode RE (second electrode or common electrode) that constitute the emission areas EA1, EA2, EA3, and EA4 may be disposed.

The pixel electrode AE may be disposed on the first overcoat layer OC1 and the third overcoat layer OC3. The pixel electrode AE may be patterned on the first overcoat layer OC1 and the third overcoat layer OC3 to define the respective emission areas EA1, EA2, EA3, and EA4. An area of the patterned pixel electrode AE may correspond to the respective emission areas EA1, EA2, EA3, and EA4. The pixel electrode AE may be formed of a transparent metal material or a semi-transmissive metal material. For example, the pixel electrode AE may be formed of a transparent conductive material (TCO, Transparent Conductive Oxide) that can transmit light, such as indium tin oxide (ITO) or indium zinc oxide (IZO). The pixel electrode AE may be formed of a semi-transmissive conductive material such as magnesium (Mg), silver (Ag), or an alloy of magnesium (Mg) and silver (Ag). For example, the pixel electrode AE formed of a semi-transmissive metal material may have improved light-extraction efficiency by a micro-cavity. The pixel electrode AE may be the anode electrode of the light emitting device ED.

The emission layer EL may be disposed on the pixel electrode AE. In addition, the emission layer EL may be a common layer formed over all of the plurality of subpixels SP1, SP2, SP3, and SP4. The emission layer EL may be disposed on the first overcoat layer OC1 and the second overcoat layer OC2. For example, the emission layer EL may be disposed on the upper surface and the slope surface of the first overcoat layer OC1 and on the upper surface of the second overcoat layer OC2. The emission layer EL may include a hole transporting layer, an emission material layer, and an electron transporting layer. For example, when a voltage is applied to the pixel electrode AE and the reflective electrode RE, holes and electrons move to the emission layer EL through the hole transporting layer and the electron transporting layer, respectively, and may recombine in the emission layer EL to emit light. For example, the emission layer EL may be a white emission layer that emits white light.

The emission layer EL according to an example embodiment of the present disclosure may include two or more emission layers to emit white light. For example, the emission layer EL may be configured as a tandem structure including a first emission layer and a second emission layer vertically stacked to emit white light by mixing first light and second light. For example, the emission layer EL may also be configured with three or four vertically stacked emission layers, but embodiments of the present disclosure are not limited thereto.

The reflective electrode RE may be disposed on the emission layer EL. In addition, the reflective electrode RE may be a common layer formed over all of the plurality of subpixels SP1, SP2, SP3, and SP4. The reflective electrode RE may be disposed on the first overcoat layer OC1 and the second overcoat layer OC2. For example, the reflective electrode RE may be disposed on or cover the upper surface and the slope surface of the first overcoat layer OC1 and on the upper surface of the second overcoat layer OC2. The reflective electrode RE may be disposed on the pixel electrode AE and the emission layer EL that are in contact with each other to constitute the emission areas EA1, EA2, EA3, and EA4. For example, the reflective electrode RE may be formed of a metal material having high reflectance, such as a laminated structure of titanium and aluminum (Ti/Al/Ti), a laminated structure of aluminum and ITO (ITO/Al/ITO), an Ag alloy, a laminated structure of an Ag alloy and ITO (ITO/Ag alloy/ITO), a MoTi alloy, and a laminated structure of a MoTi alloy and ITO (ITO/MoTi alloy/ITO). The Ag alloy may be an alloy of silver (Ag), palladium (Pd), and copper (Cu). The MoTi alloy may be an alloy of molybdenum (Mo) and titanium (Ti). The reflective electrode RE may be a cathode electrode of the light emitting device ED.

According to an example embodiment of the present disclosure, the first overcoat layer OC1 may have a slope surface OC1s on a side surface, and the second overcoat layer OC2 may have a height lower than that of the first overcoat layer OC1, whereby a groove of positive-taper shape may be formed by a step between the adjacent first overcoat layer OC1 and second overcoat layer OC2. Accordingly, the reflective electrode RE disposed on the first and second overcoat layers OC1 and OC2 may provide a side-mirror-type structure that wraps around the slope surface OC1s of the first overcoat layer OC1.

Accordingly, in the display panel 110 according to an example embodiment of the present disclosure, light emitted from the emission areas EA1, EA2, EA3, and EA4 may be reflected by the reflective electrode RE disposed on the slope surface OC1s of the first overcoat layer OC1 to form a light-extraction path in which the light is converged downward, thereby improving light-extraction efficiency. In addition, according to an example embodiment of the present disclosure, a portion of light emitted from the emission areas EA1, EA2, EA3, and EA4 may be totally internally reflected at an interface between the at least one color filter CF1, CF3, and CF4 and the second overcoat layer OC2 to form an additional light-extraction path. In addition, among light emitted from the emission areas EA1, EA2, EA3, and EA4, a light path traveling toward other adjacent subpixels may be changed by the second overcoat layer OC2 so that an additional light-extraction path may be formed through the auxiliary emission area S_EA disposed in the second overcoat layer OC2. Accordingly, light extraction of the display panel 110 may be further improved.

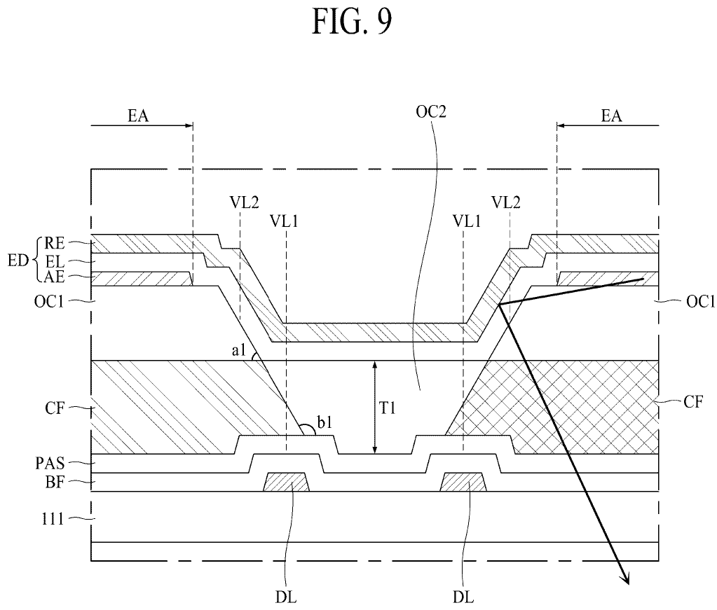

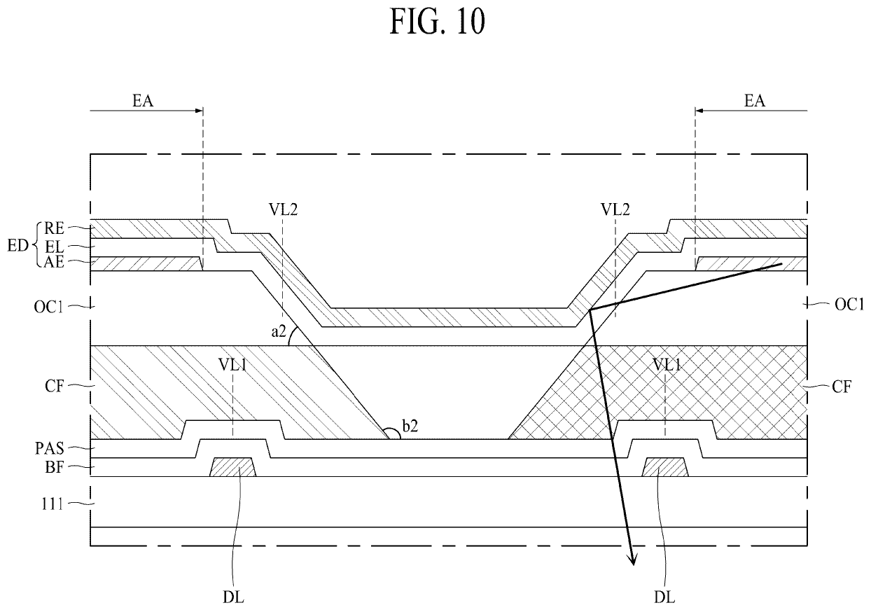

FIG. 9 illustrates adjacent subpixels according to another example embodiment of the present disclosure. FIG. 10 illustrates adjacent subpixels according to another example embodiment of the present disclosure.

As shown in FIGS. 9 and 10, the display panel 110 according to another example embodiment of the present disclosure may be arranged such that, depending on angles b1 and b2 between a slope surface of the second overcoat layer OC2 and the at least one insulating layer BF and PAS, a center position of each of the data lines DL (or a center position of the first and second portions of the first power voltage line, or a center position of the first and second portions of the reference voltage line) becomes closer to or farther from the slope surface of the second overcoat layer OC2.

As shown in FIG. 9, when an imaginary line that vertically passes through a center of each data line DL is referred to as a first line VL1, and an imaginary line parallel to the first line VL1 at a center of the slope surface of the first overcoat layer OC1 is referred to as a second line VL2, a slope angle a1 of the first overcoat layer OC1 is defined as an angle between the substrate 111 and the slope surface of the first overcoat layer OC1, and may be formed to be 45 degrees or greater. In addition, a slope surface of the second overcoat layer OC2 may have a corresponding angle to the slope surface of the first overcoat layer OC1, and, as the slope angle a1 of the first overcoat layer OC1 increases, a slope angle b1 of the second overcoat layer OC2 may decrease. Accordingly, the reflective electrode RE disposed on the slope surface of the first overcoat layer OC1 may form a light-extraction path that concentrates light, emitted from the emission area EA, toward a center of the emission area EA. As a result, the first line VL1 may be disposed farther from the pixel electrode AE than the second line VL2. For example, the data lines DL may be disposed farther from the pixel electrode AE and closer to the slope surface of the second overcoat layer OC2.

As shown in FIG. 10, when an imaginary line that vertically passes through a center of each data line DL is referred to as a first line VL1, and an imaginary line parallel to the first line VL1 at a center of the slope surface of the first overcoat layer OC1 is referred to as a second line VL2, a slope angle a2 of the first overcoat layer OC1 is defined as an angle between the substrate 111 and the slope surface of the first overcoat layer OC1, and may be formed to be less than 45 degrees. In addition, a slope surface of the second overcoat layer OC2 may have a corresponding angle to the slope surface of the first overcoat layer OC1, and, as the slope angle a2 of the first overcoat layer OC1 decreases, a slope angle b2 of the second overcoat layer OC2 may increase. Accordingly, the reflective electrode RE disposed on the slope surface of the first overcoat layer OC1 may form a light-extraction path that expands light, emitted from the emission area EA, toward an outer periphery of the emission area EA. As a result, the first line VL1 may be disposed closer to the pixel electrode AE than the second line VL2. For example, the data lines DL may be disposed closer to the pixel electrode AE and farther from the slope surface of the second overcoat layer OC2.

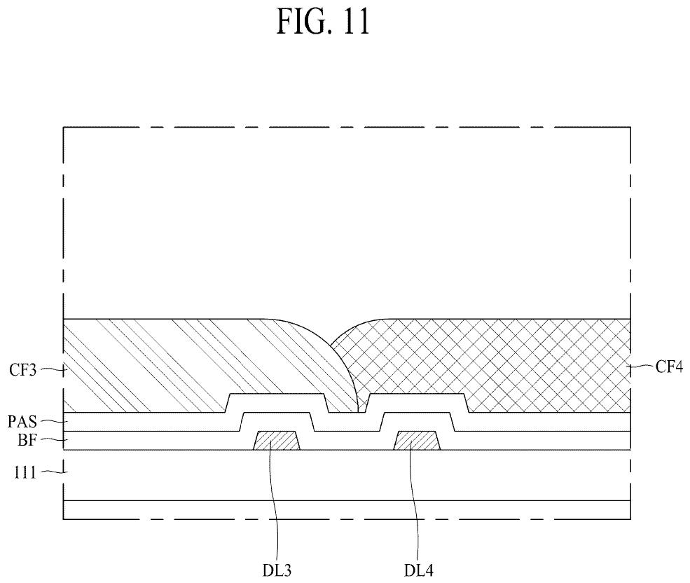

FIGS. 11 to 17 illustrate a method of manufacturing a display panel according to an example embodiment of the present disclosure. FIGS. 11 to 17 illustrate a method of manufacturing the light emitting display apparatus described with reference to FIGS. 1 to 10. In FIGS. 11 to 17, a method of manufacturing the third and fourth subpixels SP3 and SP4 is described. In the following description, the same reference numerals as in FIGS. 1 to 10 are used, and redundant description is omitted or given briefly.

As shown in FIG. 11, at least one voltage signal line may be patterned on the substrate 111, and the buffer layer BF may be formed on an entire surface of the substrate 111. The at least one voltage signal line may include the data lines DL, the first power voltage line DVL, and the reference voltage line RVL. For example, the at least one voltage signal line may be the third and fourth data lines DL3 and DL4. The passivation layer PAS may be formed on the buffer layer BF, and the at least one color filter CF may be patterned on the passivation layer PAS. For example, the third and fourth color filters CF3 and CF4 may be patterned on the passivation layer PAS. At this time, an edge portion of the third color filter CF3 may be formed to overlap the third data line DL3, and an edge portion of the fourth color filter CF4 may be formed to overlap the fourth data line DL4.

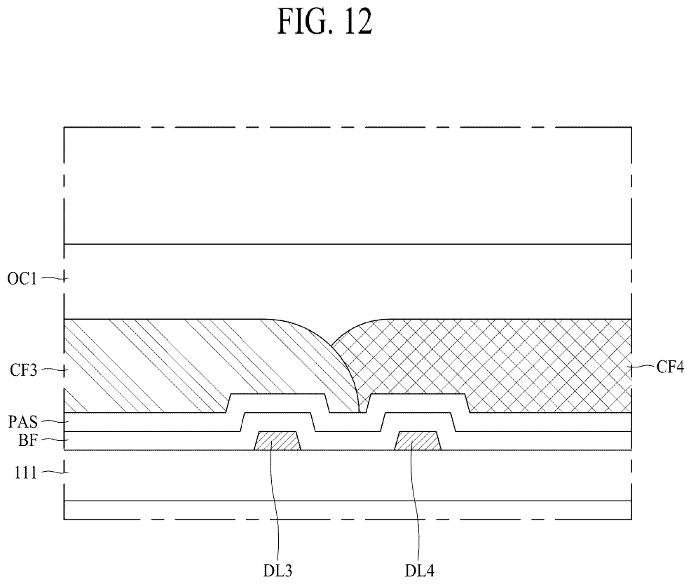

As shown in FIG. 12, the first overcoat layer OC1 may be formed on the third and fourth color filters CF3 and CF4. The first overcoat layer OC1 may be formed to cover entire surfaces of the third and fourth color filters CF3 and CF4.

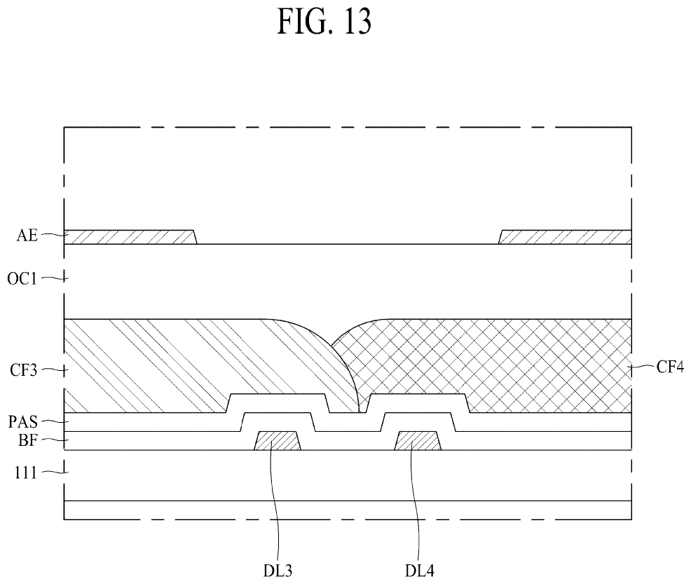

As shown in FIG. 13, the pixel electrode AE may be patterned on the first overcoat layer OC1. The pixel electrode AE may be patterned to define the emission areas EA3 and EA4. For example, the emission areas EA3 and EA4 may correspond to areas of the pixel electrode AE patterned and disposed on the first overcoat layer OC1.

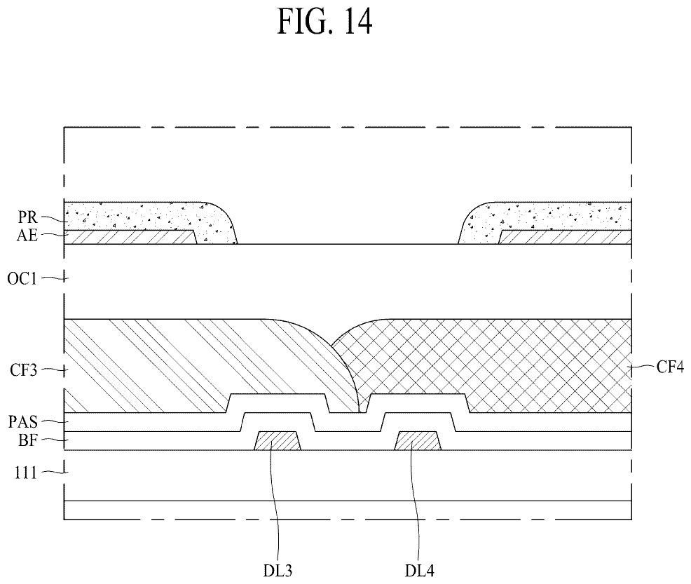

As shown in FIG. 14, a photoresist PR may be disposed on the first overcoat layer OC1. The photoresist PR may cover the pixel electrode AE and may be disposed at a position where a slope surface can be formed in the first overcoat layer OC1 and the color filters CF3 and CF4. For example, slope surfaces of the first overcoat layer OC1 and the color filters CF3 and CF4 may be determined according to a slope angle of an end portion of the photoresist PR. The slope angle of the slope surfaces of the first overcoat layer OC1 and the color filters CF3 and CF4 may be determined in proportion to the slope angle of the end portion of the photoresist PR.

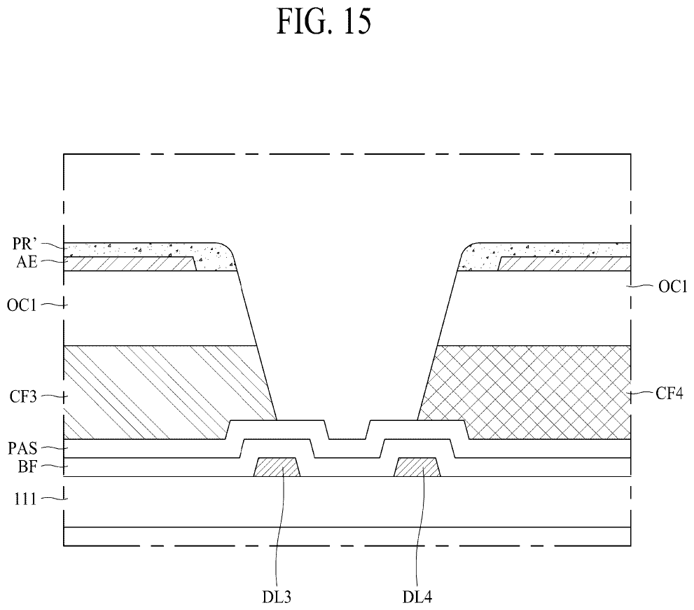

As shown in FIG. 15, the first overcoat layer OC1 and the third and fourth color filters CF3 and CF4 may be patterned through a dry etching process using the photoresist PR as a mask. In this case, the first overcoat layer OC1 and the third and fourth color filters CF3 and CF4 may be patterned to have the same slope angle. As a result, a groove having a slope surface with a positive taper may be formed between a portion where the first overcoat layer OC1 and the third color filter CF3 overlap and a portion where the first overcoat layer OC1 and the fourth color filter CF4 overlap.

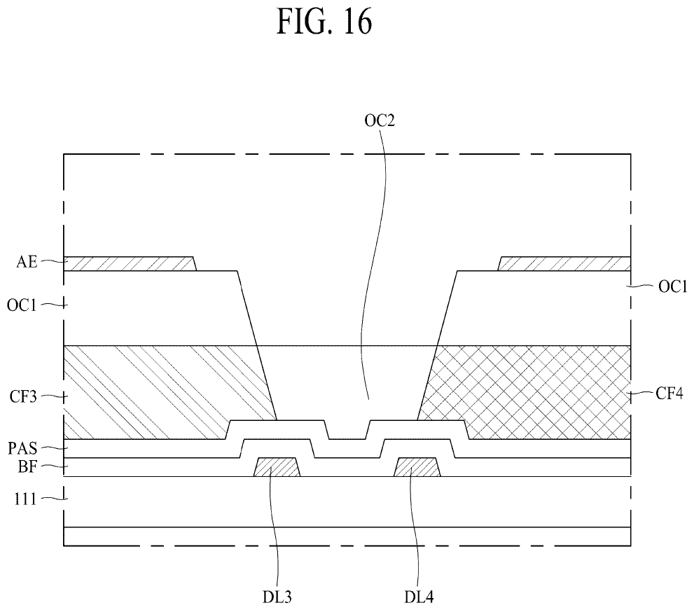

As shown in FIG. 16, the second overcoat layer OC2 may be formed in the groove between the portion where the first overcoat layer OC1 and the third color filter CF3 overlap and the portion where the first overcoat layer OC1 and the fourth color filter CF4 overlap. The second overcoat layer OC2 may be formed to fill a part of the groove. The second overcoat layer OC2 may be formed to have a height equal to each of heights of the third and fourth color filters CF3 and CF4.

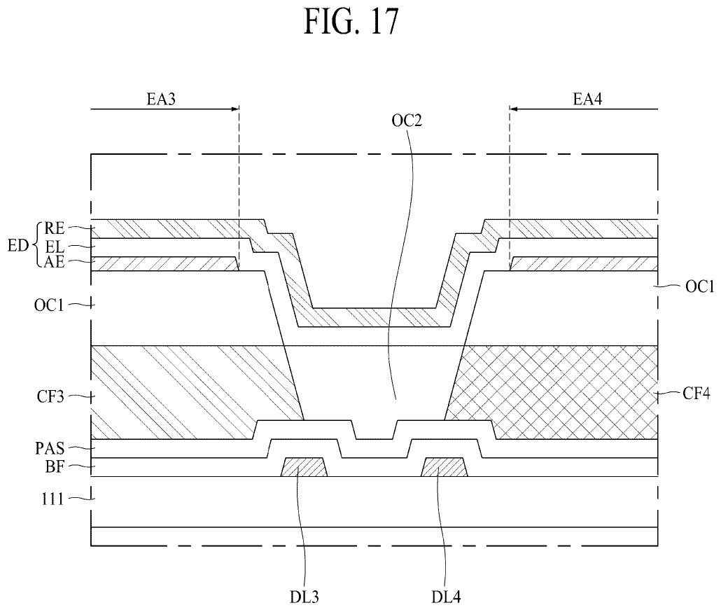

As shown in FIG. 17, the emission layer EL and the reflective electrode RE may be sequentially formed on an entire surface. At this time, the first overcoat layer OC1 may have a slope surface on a side surface, and the second overcoat layer OC2 may have a lower height than the first overcoat layer OC1. Thus, a groove having a positive taper shape may be formed by a step difference between the first and second overcoat layers OC1 and OC2. Since the emission layer EL and the reflective electrode RE are formed on an entire surface of the substrate 111, they may be formed to have slope surfaces following a groove shape formed by the first and second overcoat layers OC1 and OC2. Accordingly, the reflective electrode RE disposed on the first and second overcoat layers OC1 and OC2 may provide a side-mirror-type structure surrounding the first overcoat layer OC1.

According to an example embodiment of the present disclosure, a manufacturing method of the light emitting display apparatus may minimize or reduce process errors by simultaneously patterning the first overcoat layer OC1 and the color filter CF through a single dry etching process. In addition, grooves and reflective electrodes RE having slope surfaces between subpixels can be formed without adding a separate mask process (for example, a halftone mask process). Furthermore, by disposing the second overcoat layer OC2 having a refractive index different from that of the first overcoat layer OC1 in the groove between subpixels, an additional light-extraction path can be formed. Therefore, light-extraction efficiency of the light emitting display apparatus may be improved without an increase in manufacturing process complexity or cost.

A light emitting display apparatus according to one or more example embodiments of the present disclosure will be described below.

A light emitting display apparatus according to one or more embodiments of the present disclosure may include a substrate including a plurality of subpixels having an emission area and a non-emission area, a pixel circuit disposed in the non-emission area on the substrate, at least one insulating layer disposed on the pixel circuit, a color filter disposed on the at least one insulating layer and corresponding to at least some of the plurality of subpixels, a first overcoat layer disposed on the color filter, a second overcoat layer disposed on the at least one insulating layer between color filters that are adjacent to each other, and a reflective electrode disposed on the first overcoat layer and the second overcoat layer.

According to one or more embodiments of the present disclosure, the first overcoat layer may have a higher refractive index than the second overcoat layer, and the second overcoat layer may have a lower refractive index than the color filter.

According to one or more embodiments of the present disclosure, a difference in refractive index between the color filter and the first overcoat layer may be smaller than a difference in refractive index between the color filter and the second overcoat layer.

According to one or more embodiments of the present disclosure, the first overcoat layer and the color filter may overlap the emission area, and the second overcoat layer may overlap the non-emission area.

According to one or more embodiments of the present disclosure, the first overcoat layer and the color filter each may have an upper surface width smaller than a lower surface width and may have a slope surface with a positive taper on a side surface.

According to one or more embodiments of the present disclosure, the slope surface of the first overcoat layer may have a slope angle equal to a slope angle of the slope surface of the color filter within a range of process tolerance.

According to one or more embodiments of the present disclosure, the second overcoat layer may have a height equal to a height of the color filter within a range of process tolerance.

According to one or more embodiments of the present disclosure, the second overcoat layer may have an upper surface width greater than a lower surface width and may have a slope surface with a negative taper on a side surface, and the slope surface of the second overcoat layer and the slope surface of the color filter may face each other and may have corresponding slope angles.

According to one or more embodiments of the present disclosure, the reflective electrode may cover the upper surface and the slope surface of the first overcoat layer and the upper surface of the second overcoat layer.

According to one or more embodiments of the present disclosure, at least one of the plurality of subpixels may be a white subpixel in which the color filter is not disposed, and the light emitting display apparatus may further include a third overcoat layer disposed on the at least one insulating layer corresponding to the white subpixel and formed of the same material as the first overcoat layer.

According to one or more embodiments of the present disclosure, the third overcoat layer may have a height equal to a height of an overlapped structure of the first overcoat layer and the color filter within a range of process tolerance.

According to one or more embodiments of the present disclosure, the third overcoat layer may have an upper surface width smaller than a lower surface width and may have a slope surface with a positive taper on a side surface, and the slope surface of the third overcoat layer may have a slope angle equal to a slope angle of the slope surface of the first overcoat layer or the slope surface of the color filter within a range of process tolerance.

According to one or more embodiments of the present disclosure, the plurality of subpixels may be arranged in a first direction, and the light emitting display apparatus may further include at least one voltage signal line extending in a second direction intersecting the first direction between adjacent subpixels among the plurality of subpixels, and an auxiliary emission area not overlapping the at least one voltage signal line between the adjacent subpixels.

According to one or more embodiments of the present disclosure, the second overcoat layer may overlap the auxiliary emission area.

According to one or more embodiments of the present disclosure, the auxiliary emission area may emit light having a color corresponding to a color of a first subpixel among the adjacent subpixels, a color corresponding to a color of a second subpixel among the adjacent subpixels, or a color different from colors of the first and second subpixels.

According to one or more embodiments of the present disclosure, the at least one voltage signal line may include a first voltage signal line portion adjacent to a first subpixel among the adjacent subpixels and a second voltage signal line portion adjacent to a second subpixel among the adjacent subpixels, and centers of the first and second voltage signal line portions may overlap or not overlap the second overcoat layer in a vertical direction.

According to one or more embodiments of the present disclosure, according to an angle between a slope surface of the second overcoat layer and the at least one insulating layer, center positions of the first and second voltage signal line portions may be disposed to become closer to or farther from the slope surface of the second overcoat layer.

According to one or more embodiments of the present disclosure, the at least one voltage signal line may include a first data line corresponding to the first subpixel and a second data line corresponding to the second subpixel, the first voltage signal line portion may be the first data line, the second voltage signal line portion may be the second data line, and the auxiliary emission area may be formed between the first data line and the second data line.

According to one or more embodiments of the present disclosure, the at least one voltage signal line may include a plurality of data lines corresponding to the plurality of subpixels, and at least one power voltage line having a width greater than widths of at least two of the plurality of data lines, and the at least one power voltage line may include an opening slit pattern formed between the first and second voltage signal line portions, and the auxiliary emission area may be formed to overlap the opening slit pattern.

According to one or more embodiments of the present disclosure, the emission area may correspond to a light emitting device including a pixel electrode, an emission layer, and the reflective electrode of each subpixel, and the non-emission area may include a first non-emission area in which the pixel circuit is disposed and a second non-emission area between adjacent subpixels among the plurality of subpixels, the light emitting display apparatus may further include a bank portion disposed between the pixel electrode and the emission layer in the first non-emission area, and the second overcoat layer may surround a remaining outer portion of the emission area except for the first non-emission area in which the bank portion is disposed.

The above-described feature, structure, and effect of the present disclosure are included in at least one example embodiment of the present disclosure, but are not limited to only one embodiment. Furthermore, the feature, structure, and effect described in at least one example embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure cover the modifications and variations of this disclosure provided they come within the scope of the appended claims and their equivalents.

What is claimed is:

1. A light emitting display apparatus, comprising:
a substrate including a plurality of subpixels having an emission area and a non-emission area;
a pixel circuit disposed in the non-emission area on the substrate;
at least one insulating layer disposed on the pixel circuit;
a color filter disposed on the at least one insulating layer and corresponding to at least some of the plurality of subpixels;
a first overcoat layer disposed on the color filter;
a second overcoat layer disposed on the at least one insulating layer between color filters that are adjacent to each other; and
a reflective electrode disposed on the first overcoat layer and the second overcoat layer.

2. The light emitting display apparatus of claim 1, wherein the first overcoat layer has a higher refractive index than the second overcoat layer, and the second overcoat layer has a lower refractive index than the color filter.

3. The light emitting display apparatus of claim 1, wherein a difference in refractive index between the color filter and the first overcoat layer is smaller than a difference in refractive index between the color filter and the second overcoat layer.

4. The light emitting display apparatus of claim 1, wherein the first overcoat layer and the color filter overlap the emission area, and the second overcoat layer overlaps the non-emission area.

5. The light emitting display apparatus of claim 1, wherein the first overcoat layer and the color filter each have an upper surface width smaller than a lower surface width and have a slope surface with a positive taper on a side surface.

6. The light emitting display apparatus of claim 5, wherein the slope surface of the first overcoat layer has a slope angle equal to a slope angle of the slope surface of the color filter within a range of process tolerance.

7. The light emitting display apparatus of claim 5, wherein the second overcoat layer has a height equal to a height of the color filter within a range of process tolerance.

8. The light emitting display apparatus of claim 7, wherein the second overcoat layer has an upper surface width greater than a lower surface width and has a slope surface with a negative taper on a side surface, and the slope surface of the second overcoat layer and the slope surface of the color filter face each other and have corresponding slope angles.

9. The light emitting display apparatus of claim 7, wherein the reflective electrode covers the upper surface and the slope surface of the first overcoat layer and the upper surface of the second overcoat layer.

10. The light emitting display apparatus of claim 1, wherein:
at least one of the plurality of subpixels is a white subpixel in which the color filter is not disposed; and
the light emitting display apparatus further comprises a third overcoat layer disposed on the at least one insulating layer corresponding to the white subpixel and formed of the same material as the first overcoat layer.

11. The light emitting display apparatus of claim 10, wherein the third overcoat layer has a height equal to a height of an overlapped structure of the first overcoat layer and the color filter within a range of process tolerance.

12. The light emitting display apparatus of claim 11, wherein:
the third overcoat layer has an upper surface width smaller than a lower surface width and has a slope surface with a positive taper on a side surface; and
the slope surface of the third overcoat layer has a slope angle equal to a slope angle of the slope surface of the first overcoat layer or the slope surface of the color filter within a range of process tolerance.

13. The light emitting display apparatus of claim 1, wherein:
the plurality of subpixels are arranged in a first direction; and
the light emitting display apparatus further comprises:
at least one voltage signal line extending in a second direction intersecting the first direction between adjacent subpixels among the plurality of subpixels; and
an auxiliary emission area not overlapping the at least one voltage signal line between the adjacent subpixels.

14. The light emitting display apparatus of claim 13, wherein the second overcoat layer overlaps the auxiliary emission area.

15. The light emitting display apparatus of claim 13, wherein the auxiliary emission area emits light having a color corresponding to a color of a first subpixel among the adjacent subpixels, a color corresponding to a color of a second subpixel among the adjacent subpixels, or a color different from colors of the first and second subpixels.

16. The light emitting display apparatus of claim 13, wherein:
the at least one voltage signal line includes a first voltage signal line portion adjacent to a first subpixel among the adjacent subpixels and a second voltage signal line portion adjacent to a second subpixel among the adjacent subpixels; and
centers of the first and second voltage signal line portions overlap or do not overlap the second overcoat layer in a vertical direction.

17. The light emitting display apparatus of claim 16, wherein, according to an angle between a slope surface of the second overcoat layer and the at least one insulating layer, center positions of the first and second voltage signal line portions are disposed to become closer to or farther from the slope surface of the second overcoat layer.

18. The light emitting display apparatus of claim 16, wherein:
the at least one voltage signal line includes a first data line corresponding to the first subpixel and a second data line corresponding to the second subpixel;
the first voltage signal line portion is the first data line;
the second voltage signal line portion is the second data line; and
the auxiliary emission area is formed between the first data line and the second data line.

19. The light emitting display apparatus of claim 16, wherein the at least one voltage signal line includes:
a plurality of data lines corresponding to the plurality of subpixels; and
at least one power voltage line having a width greater than widths of at least two of the plurality of data lines, and
wherein the at least one power voltage line includes an opening slit pattern formed between the first and second voltage signal line portions, and the auxiliary emission area is formed to overlap the opening slit pattern.

20. The light emitting display apparatus of claim 1, wherein:
the emission area corresponds to a light emitting device including a pixel electrode, an emission layer, and the reflective electrode of each subpixel;
the non-emission area includes a first non-emission area in which the pixel circuit is disposed and a second non-emission area between adjacent subpixels among the plurality of subpixels;
the light emitting display apparatus further comprises a bank portion disposed between the pixel electrode and the emission layer in the first non-emission area; and
the second overcoat layer surrounds a remaining outer portion of the emission area except for the first non-emission area in which the bank portion is disposed.
